(19) United States
(12) Patent Application Publication
(10) Pub. No.: US 2023/0254998 A1
(43) Pub. Date: Aug. 10, 2023

(54) HEAT DISSIPATION MODULE WITH SHOCK RESISTING EFFECT

(71) Applicant: CELSIA TECHNOLOGIES TAIWAN, INC., Taoyuan City (TW)

(72) Inventors: George A. Meyer IV, Morgan Hill, CA (US); Chien-Hung SUN, Taoyuan City (TW)

(21) Appl. No.: 17/669,062

(22) Filed: Feb. 10, 2022

(51) Int. Cl. H05K 7/20; F28D 15/04

(52) U.S. Cl. CPC H05K 7/20336; H05K 7/2039; F28D 15/04

(57) ABSTRACT

A heat dissipation module with a shock resisting effect is provided. The heat dissipation module includes a heat absorbing unit, a heat dissipating unit and at least one flexible heat conducting bundle. The heat absorbing unit has a first installing surface. The heat dissipating unit is disposed corresponding to the heat absorbing unit and has a second installing surface facing the first installing surface. The flexible heat conducting bundle is connected between the first installing surface and the second installing surface, and used for transferring heat of the heat absorbing unit to the heat dissipating unit to dissipate the heat. Accordingly, the heat dissipation module is provided with a flexible stretching function and a shock resisting effect.

### BACKGROUND OF THE DISCLOSURE

### Technical Field

The present disclosure relates to a heat dissipation module, particularly to a heat dissipation module with a shock resisting effect.

### Description of Related Art

With the rapid development of technology, various kinds of electronic devices have been developed. There is a trend of making the electronic device be small and have a high speed, the performance of a heat dissipation module in the electronic device has an important role, thus an a chip or an electric circuit board may be effectively prevented from being overly heated via an excellent heat dissipating effect, and the service life may be greatly prolonged and the electronic device may be operated with a high performance.

However, a related-art heat dissipation module is disposed between a heat source and a machine case of the electronic device, when the electronic device is impacted by an impact force or applied with an external force, the impact force may be directly transferred from the machine case of the electronic device to the heat source through the heat dissipation module, and the heat source may be damaged or broken. For a military-grade device requiring a higher shock resisting level, a heat dissipation module with a shock resisting effect needs to be provided.

Accordingly, the applicant of the present disclosure has devoted himself for improving the mentioned disadvantages.

### SUMMARY OF THE DISCLOSURE

The present disclosure is to provide a heat dissipation module with a shock resisting effect and having a flexible stretching function.

Accordingly, the present disclosure provides a heat dissipation module with a shock resisting effect, the heat dissipation module including a heat absorbing unit, a heat dissipating unit and at least one flexible heat conducting bundle. The heat absorbing unit has a first installing surface. The heat dissipating unit is disposed corresponding to the heat absorbing unit and has a second installing surface facing the first installing surface. The flexible heat conducting bundle is connected between the first installing surface and the second installing surface, and used for transferring heat of the heat absorbing unit to the heat dissipating unit to dissipate the heat.

Advantages achieved by the present disclosure are as follows. The flexible heat conducting bundles is formed through a plurality of metal strings being mutually twisted or through a metal woven net being reeled, thus the flexible heat conducting bundle provides certain flexibility and is capable of being bent and deformed. With a plurality of fastening holes being respectively formed on the heat absorbing unit and the heat dissipating unit, two ends of each of the flexible heat conducting bundles may be fastened in the fastening holes. With a bending segment formed on each of the flexible heat conducting bundles, when the heat dissipating module is subjected to a stretching or a shaking situation, a stretching and buffering effect is provided to prevent an impact force from being directly applied to generate damages or cracks.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing the assembly according to a first embodiment of the present disclosure;

FIG. 2 is a perspective exploded view according to the first embodiment of the present disclosure;

FIG. 3 is a side view according to the first embodiment of the present disclosure;

FIG. 4 is a schematic view showing an operating status according to the first embodiment of the present disclosure;

FIG. 5 is a cross sectional view according to a second embodiment of the present disclosure; and

FIG. 6 is a side view according to a third embodiment of the present disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

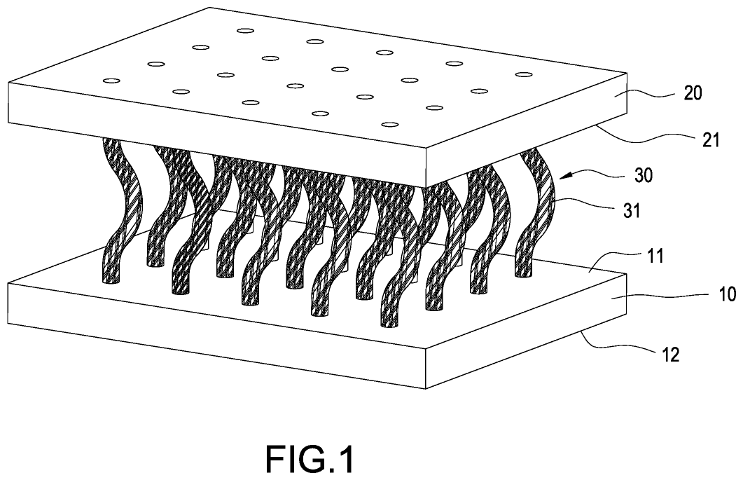

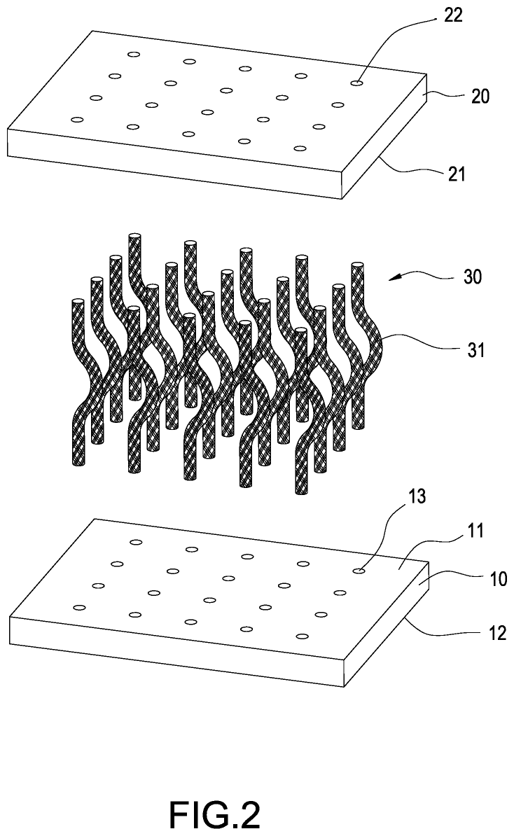

Please refer from FIG. 1 to FIG. 4, the present disclosure provides a heat dissipation module with a shock resisting effect, which is used for dissipating heat generated by a heat source A, and mainly includes a heat absorbing unit 10, a heat dissipating unit 20 and at least one flexible heat conducing bundle 30.

In some embodiments, the heat absorbing unit 10 is a metal plate (for example a copper plate or an aluminum plate) having a good heat conducting performance, but here is not intended to be limiting, any plate member having a good heat conducting performance may be adopted and the plate member may be formed in any geometric shape. The heat absorbing unit 10 has a first installing surface 11 and a contact surface 12 opposite to each other, the contact surface 12 is attached to a surface of the heat source A to make the heat generated by the heat source A be transferred to the heat absorbing unit 10.

The heat dissipating unit 20 is disposed corresponding to the heat absorbing unit 10, and has a second installing surface 21 facing the first installing surface 11. In some embodiments, the heat dissipating unit 20 is a metal plate (for example a copper plate or an aluminum plate) having a good heat conducting performance, but here is not intended to be limiting, any plate member having a good heat conducting performance may be adopted and the plate member may be formed in any geometric shape.

In some embodiments, there are a plurality of (equal to or more than two) of flexible heat conducting bundles 30, but here is not intended to be limiting, the amount of the flexible heat conducting bundles 30 may be adjusted according to actual needs of a designer, intervals between the flexible heat conducting bundles 30 and the amount of the flexible heat conducting bundles 30 shown in each figure are provided as examples and not intended to be limiting. Each of the flexible heat conducting bundles 30 is connected between the first installing surface 11 and the second installing surface 21, and used for transferring heat absorbed by the heat absorbing unit 10 to the heat dissipating unit 20 to be dissipated. Each of the flexible heat conducting bundles 30 may be formed through a plurality of metal strings being mutually twisted in a bundling manner, or through a metal woven net being reeled in a bundling manner, thus the flexible heat conducting bundle 30 provides certain flexibility and is capable of being bent and deformed. In some embodiments, the metal string or the metal woven net is made of any one of silver, copper, aluminum, iron, or steel, or an alloy thereof, thereby being provided with a good heat conducting effect, but here is not intended to be limiting.

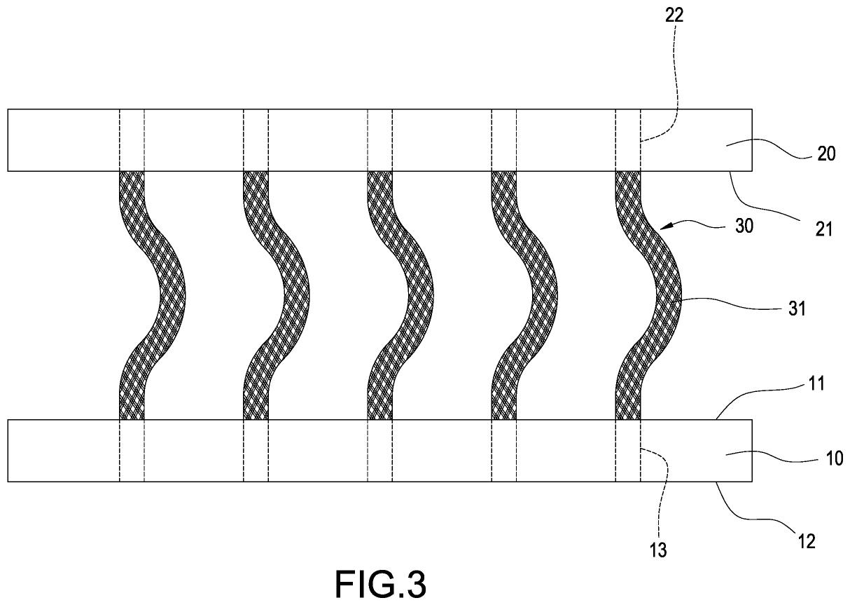

Details are provided as follows. The heat absorbing unit 10 and the heat dissipating unit 20 respectively have a plurality of fastening holes 13, 22, and two ends of each of the flexible heat conducting bundles 30 are fastened in each of the fastening holes 13, 22. The fastening holes 13, 22 may be a blind hole or a through hole, but here is not intended to be limiting. In some embodiments, the two ends of each of the flexible heat conducting bundles 30 are disposed and welded in each of the fastening holes 13, 22, but here is not intended to be limiting. For example, each of the flexible heat conducting bundles 30 may be fastened with the heat absorbing unit 10 and the heat dissipating unit 20 by a riveting, an adhering or a soldering method, as long as a fastening effect may be effectively achieved. Each of the flexible heat conducting bundles 30 is pre-formed with at least one bending segment 31 before being fastened. As such, when the heat dissipating module of the present disclosure is subjected to a stretching or a shaking situation, the bending segment 31 of each of the flexible heat conducting bundles 30 is stretched for buffering to prevent an impact force from being directly applied to generate damages or cracks. Please refer to FIG. 3, in some embodiments, there is one bending segment 31 in each of the flexible heat conducting bundles 30, and a bending direction of each of the bending segments 31 is in the same direction, but here is not intended to be limiting.

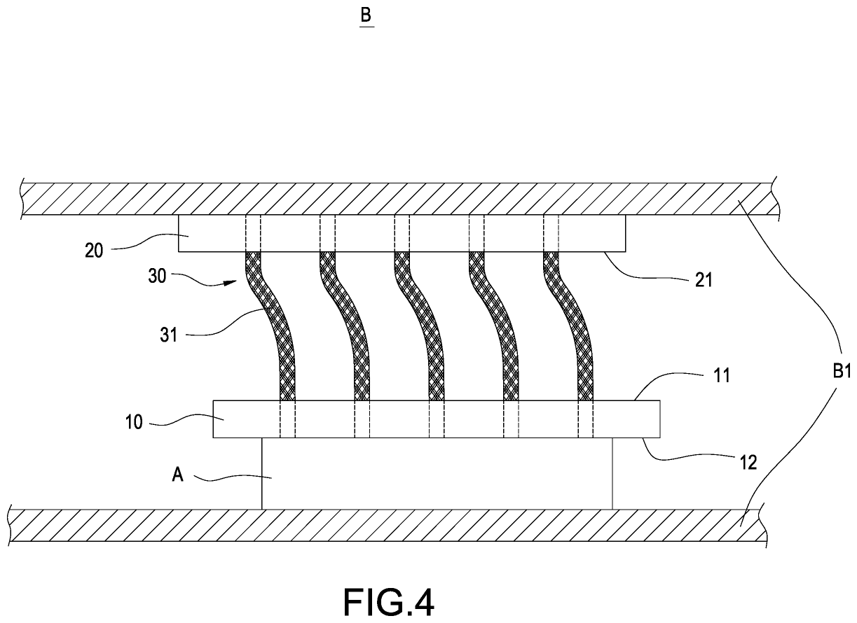

Please refer to FIG. 4, which is a schematic view showing the present disclosure being applied in an electronic device. An electronic device B includes a machine case B1 and a heat source A (for example a chip, a die or an electric circuit board) disposed in the machine case B1. The contact surface 12 of the heat absorbing unit 10 is attached to a surface of the heat source A, and the heat dissipating unit 20 is directly disposed on the machine case B1. Accordingly, when the electronic device B is impacted by an external force to make the machine case B1 be instantly and outwardly pulled, the bending segment 31 of each of the flexible heat conducting bundles 30 is stretched for buffering to provide a shock resisting effect, and the impact force is not directly transferred to the heat source A to avoid damages.

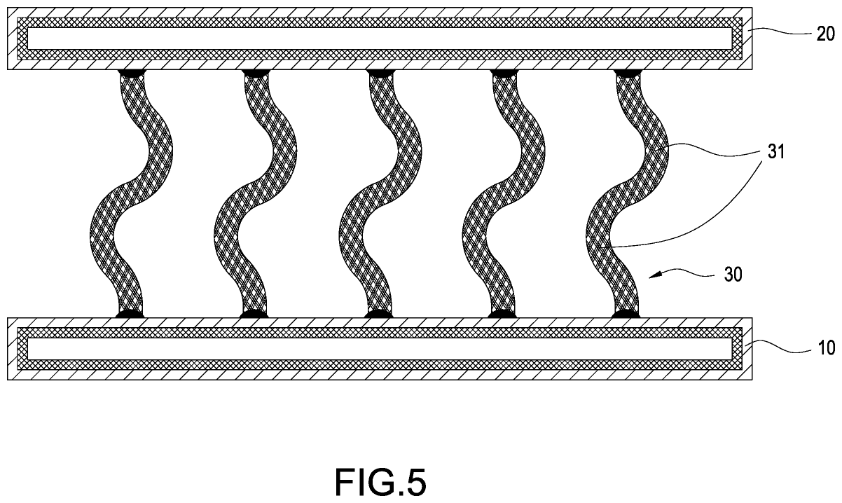

Please refer to FIG. 5, which provides a second embodiment of the present disclosure. The difference between the second embodiment and other exemplary embodiments is that there are two bending segments 31 in each of the flexible heat conducting bundles 30, and the heat dissipating unit 20 and the heat absorbing unit 10 are a vapor chamber or a thinned heat pipe. Bending directions of the two bending segments 31 of each of the flexible heat conducting bundles 30 are opposite to form an S-shaped status. As such, a stretchable space and a stretchable length of each of the flexible heat conducting bundles 30 are increased to provide a better shock resisting effect. The vapor chamber or the thinned heat pipe adopted as the heat absorbing unit 10 may perform a primary heat dissipation when the heat of the heat source A is conducted to the heat absorbing unit 10, and a secondary heat dissipation may be performed through conduction via each of the flexible heat conducting bundles 30, lastly the vapor chamber or the thinned heat pipe adopted as the heat dissipating unit 20 performs a final heat dissipation, thus a high-performance heat dissipating effect is provided. In some embodiments, one of the heat dissipating unit 20 and the heat absorbing unit 10 of the present disclosure is the vapor chamber or the thinned heat pipe, and the other is the metal plate having a desirable heat conducting performance as disclosed in the first embodiment, and the combination may be decided according to actual needs and cost concerns, here is not intended to be limiting.

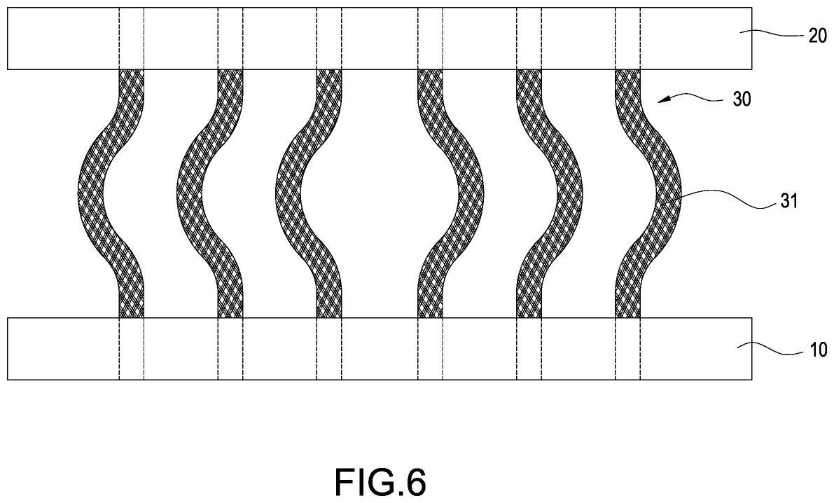

Please refer to FIG. 6, which provides a third embodiment of the present disclosure. The difference between the third embodiment and other exemplary embodiments is that there is one bending segment 31 in each of the flexible heat conducting bundles 30. Each of the bending segments 31 is bent outward, thus the bending segments 31 of the flexible heat conducting bundles 30 are in a radial manner when being viewed from the top, each of the flexible heat conducting bundles 30 may surround a central position in a lantern-like manner, thus air circulation in each of the flexible heat conducting bundles 30 may be enhanced, and the heat dissipating effect of each of the flexible heat conducting bundles 30 may be increased.

While this disclosure has been described by means of specific embodiments, numerous modifications and variations could be made thereto by those skilled in the art without departing from the scope and spirit of this disclosure set forth in the claims.

What is claimed is:

1. A heat dissipation module, comprising:
a heat absorbing unit, comprising a first installing surface;
a heat dissipating unit, disposed corresponding to the heat absorbing unit and comprising a second installing surface facing the first installing surface; and
at least one flexible heat conducting bundle, connected between the first installing surface and the second installing surface, and configured to transfer heat of the heat absorbing unit to the heat dissipating unit.

2. The heat dissipation module according to claim 1, wherein the flexible heat conducting bundle comprises at least one bending segment.

3. The heat dissipation module according to claim 2, wherein the flexible heat conducting bundle is multiple in number, and the bending segments are bent in a same direction.

4. The heat dissipation module according to claim 2, wherein the flexible heat conducting bundle is multiple in number, and the bending segments are bent outward in a radial manner.

5. The heat dissipation module according to claim 2, wherein the bending segment is two in number, and the two bending segments are bent in an opposite direction in an S shape manner.

6. The heat dissipation module according to claim 1, wherein the flexible heat conducting bundle comprises a plurality of metal strings mutually twisted in a bundling manner.

7. The heat dissipation module according to claim 1, wherein the flexible heat conducting bundle comprises a metal woven net reeled in a bundling manner.

8. The heat dissipation module according to claim 1, wherein the heat absorbing unit and the heat dissipating unit are any one of a metal plate, a vapor chamber or a thinned heat pipe.

9. The heat dissipation module according to claim 1, wherein the heat absorbing unit and the heat dissipating unit respectively comprise at least one fastening hole, and two ends of the flexible heat conducting bundle are fastened in each of the fastening holes of the heat absorbing unit and the heat dissipating unit.

10. The heat dissipation module according to claim 9, wherein the two ends of the flexible heat conducting bundle are welded in each of the fastening holes.
